(19) United States
(12) Patent Application Publication
(10) Pub. No.: US 2013/0312820 A1
(43) Pub. Date: Nov. 28, 2013

(54) SOLAR CELL AND MANUFACTURING METHOD THEREOF

(71) Applicants: Yen-Cheng HU, Hsin-Chu (TW); Wei-Shuo Ho, Hsin-Chu (TW); Jen-Chieh Chen, Hsin-Chu (TW); Zhen-Cheng Wu, Hsin-Chu (TW)

(72) Inventors: Yen-Cheng HU, Hsin-Chu (TW); Wei-Shuo Ho, Hsin-Chu (TW); Jen-Chieh Chen, Hsin-Chu (TW); Zhen-Cheng Wu, Hsin-Chu (TW)

(73) Assignee: AU OPTRONICS CORP., Hsin-Chu (TW)

(21) Appl. No.: 13/602,625

(22) Filed: Sep. 4, 2012

(30) Foreign Application Priority Data
May 24, 2012 (CN) 201210165274.7

(51) Int. Cl. H01L 31/0232; H01L 31/0236

(52) U.S. Cl. 136/256; 136/259; 438/72; 257/E31.127

(57) ABSTRACT

A solar cell includes a semiconductor substrate and a first antireflective layer. The semiconductor substrate has a first-type semiconductor surface and a second-type semiconductor surface opposite to each other. The first antireflective layer includes a plurality of refraction convexes and a coverage layer. The refraction convexes are formed on the second-type semiconductor surface. Each refraction convex includes a first refraction part and a second refraction part. The first refraction parts are conformally coated with the respective second refraction parts, and the first refraction part is configured to have a refractive index greater than the refractive index of the second refraction part. The coverage layer is formed to cover the second-type semiconductor surface and the refraction convexes, and the coverage layer is configured to have a refractive index smaller than the refractive index of the second refraction part. A solar cell manufacturing method is also provided.

### TECHNICAL FIELD

The disclosure relates to a solar cell and a manufacturing method thereof, and more particularly to a solar cell having an antireflective layer constituted by microscopic structures and a manufacturing method thereof.

### BACKGROUND

FIG. 1 is a schematic cross-sectional view of a conventional solar cell. As shown, the conventional solar cell 1 includes a semiconductor substrate 10, a first antireflective layer 11, a second antireflective layer 12, a first electrode 13 and a second electrode 14. Specifically, the semiconductor substrate 10 has an N-type semiconductor surface 101 and a P-type semiconductor surface 102 opposite to each other. The first antireflective layer 11 is formed on the N-type semiconductor surface 101; and the second antireflective layer 12 is formed on the P-type semiconductor surface 102. The first electrode 13 is connected to the N-type semiconductor surface 101; and the second electrode 14 is connected to the P-type semiconductor surface 102.

To increase the light absorption efficiency of the solar cell 1, the saw damage removal process, for forming a plurality of microscopic pyramids 15 on the N-type semiconductor surface 101 and the P-type semiconductor surface 102, is commonly performed on the semiconductor substrate 10. In other words, the microscopic pyramids 15 are formed on the N-type semiconductor surface 101 and the P-type semiconductor surface 102 by bathing the semiconductor substrate 10 in an acid etching solution such as NaOH or KOH for the isotropic etch. However, the semiconductor substrate 10, while being processed by the wet etching texture, may be damaged if the concentration of the acid etching solution or the temperature are not controlled properly; and consequently the damaged semiconductor substrate 10 may lead to a poor conduction efficiency of the electrons and holes between the N-type semiconductor surface 101 and the P-type semiconductor surface 102 and a decreasing photoelectric conversion efficiency of solar cell 1.

### SUMMARY OF EMBODIMENTS

Therefore, one object of the present disclosure is to provide a solar cell having higher light absorption efficiency by employing an antireflective layer constituted by materials with different refractive indexes.

Another object of the present disclosure is to provide a solar cell manufacturing method; wherein the associated solar cell can have higher light absorption efficiency by forming an antireflective layer, constituted by materials with different refractive indexes, on a semiconductor substrate through the deposition processes.

An embodiment of the present disclosure provides a solar cell, which includes a semiconductor substrate and a fist antireflective layer. The semiconductor substrate has a first-type semiconductor surface and a second-type semiconductor surface opposite to each other. The fist antireflective layer includes a plurality of refraction convexes and a coverage layer. The refraction convexes are formed on the second-type semiconductor surface. Each refraction convex includes a first refraction part and a second refraction part. The first refraction parts are conformally coated with the respective second refraction parts, and the first refraction part is configured to have a refractive index greater than the refractive index of the second refraction part. The coverage layer is formed to cover the second-type semiconductor surface and the refraction convexes, and the coverage layer is configured to have a refractive index smaller than the refractive index of the second refraction part.

Another embodiment of the present disclosure provides a solar cell manufacturing method, which includes steps of: providing a semiconductor substrate with a first surface and a second surface opposite to each other; and forming a first antireflective layer on the second-type semiconductor surface, wherein the first antireflective layer comprises a plurality of refraction convexes and a coverage layer, each refraction convex comprises a first refraction part and a second refraction part, the first refraction parts are conformally coated with the respective second refraction parts, the first refraction part is configured to have a refractive index greater than the refractive index of the second refraction part, the coverage layer is formed to cover the second-type semiconductor surface and the refraction convexes, and the coverage layer is configured to have a refractive index smaller than the refractive index of the second refraction part.

In summary, according to the solar cell and the manufacturing method thereof disclosed in the present disclosure, an antireflective layer constituted by a plurality of refraction convexes and a coverage layer is formed on a semiconductor substrate; wherein each refraction convex includes a first refraction part and a second refraction part, the first refraction parts are conformally coated with the respective second refraction parts, and the first refraction part is configured to have a refractive index greater than the refractive index of the second refraction part. According to the aforementioned antireflective layer structure, the solar cell of the present disclosure can have higher light absorption efficiency as well as higher photoelectric conversion efficiency. In addition, according to the solar cell manufacturing method of the present disclosure, the semiconductor substrate is prevented from being damaged due to the texture process is omitted. Thus, a poor conduction efficiency of the electrons and holes between the N-type and P-type semiconductor surfaces is avoided.

### BRIEF DESCRIPTION OF THE DRAWINGS

The above embodiments will become more readily apparent to those ordinarily skilled in the art after reviewing the following detailed description and accompanying drawings, in which:

FIG. 1 is a schematic cross-sectional view of a conventional solar cell;

FIG. 2 is a schematic cross-sectional view of a solar cell in accordance with an embodiment of the present disclosure; and

FIGS. 3A˜3H are schematic views illustrating a manufacturing process of the solar cell 2 shown in FIG. 2.

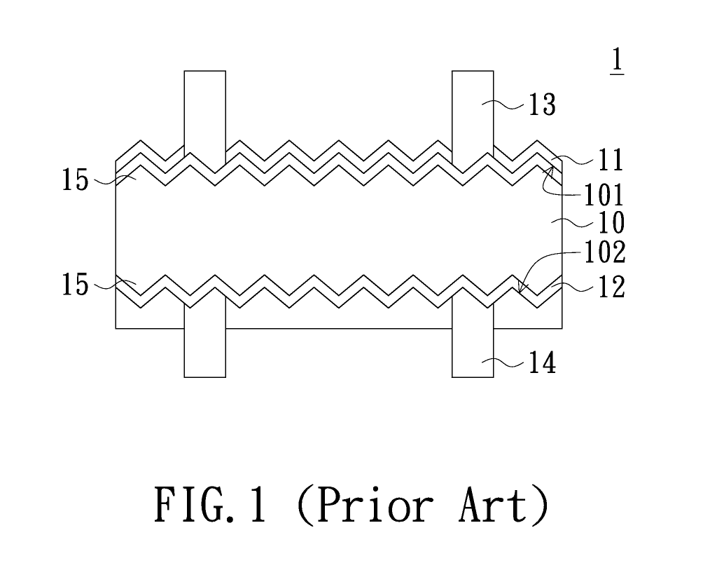

### DETAILED DESCRIPTION OF EMBODIMENTS

The disclosure will now be described more specifically with reference to the following embodiments. It is to be noted that the following descriptions of preferred embodiments are presented herein for purpose of illustration and description only. It is not intended to be exhaustive or to be limited to the precise form disclosed.

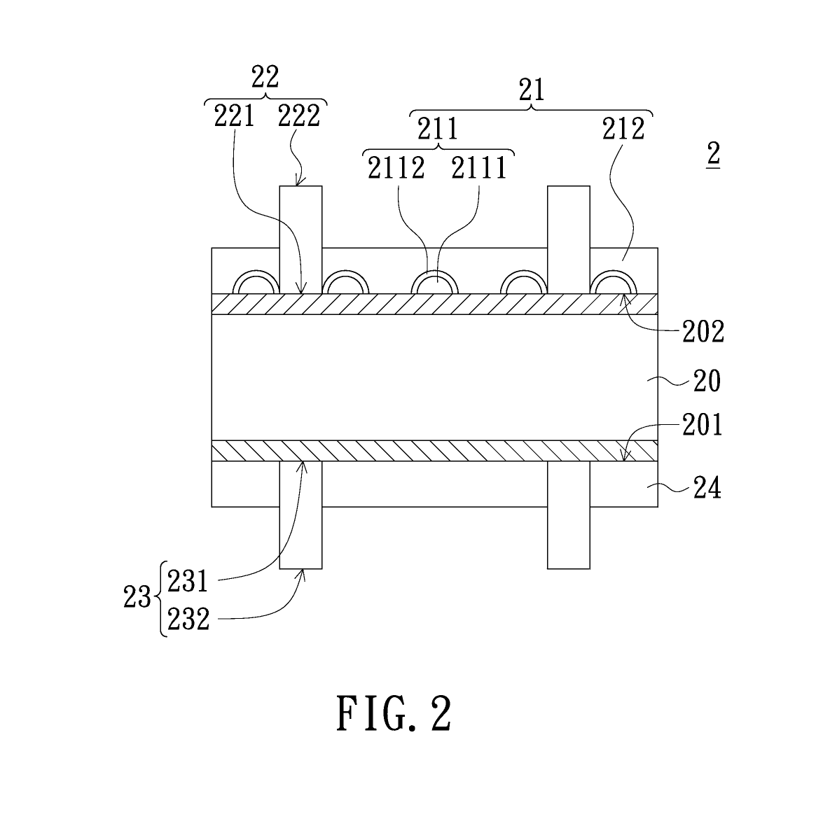

FIG. 2 is a schematic cross-sectional view of a solar cell in accordance with an embodiment of the present disclosure. As shown, the solar cell 2 in this embodiment includes a semiconductor substrate 20 and a first antireflective layer 21. The semiconductor substrate 20 has a first-type semiconductor surface 201 and a second-type semiconductor surface 202 opposite to each other. The first antireflective layer 21 includes a plurality of refraction convexes 211 and a coverage layer 212. The refraction convexes 211 are formed on the second-type semiconductor surface 202 and each include a first refraction part 2111 and a second refraction part 2112. The second refraction parts 2112 are conformally coated on the respective first refraction parts 2111; and the first refraction part 2111 has a refractive index greater than the refractive index of the second refraction part 2112. The coverage layer 212 is formed to cover the second-type semiconductor surface 202 and the refraction convexes 211; and the coverage layer 212 has a refractive index smaller than the refractive index of the second refraction part 2112.

In this embodiment, the first-type semiconductor surface 201 is a P-type semiconductor surface; and the second-type semiconductor surface 202 is an N-type semiconductor surface. In another embodiment, the first-type semiconductor surface 201 can be an N-type semiconductor surface; and the second-type semiconductor surface 202 can be a P-type semiconductor surface. In addition, the first-type semiconductor surface 201 in this embodiment functions as a back surface field of the solar cell 2 and is configured to increase the open circuit voltage so as to enhance the photoelectric conversion efficiency of the solar cell 2; and the disclosure is not limited thereto.

In this embodiment, the refraction convexes 211 have a hemispherical, semi-elliptical or arc-shaped structures with a size of 70˜100 microns. The first refraction part 2111 of the refraction convex 211 is SiC and has a refractive index of 2.6˜2.8; the second refraction part 2112 of the refraction convex 211 is SiN and has a refractive index of 1.8˜2.2; and the coverage layer 212 is SiO₂ and has a refractive index of 1.45. In other words, in this embodiment the coverage layer 212 is configured to have a refractive index greater than the refractive index of air (basically, air has a refractive index of 1.000293); the second refraction part 2112 is configured to have a refractive index greater than the refractive index of the coverage layer 212; and the first refraction part 2111 is configured to have a refractive index greater than the refractive index of the second refraction part 2112. Thus, the sunlight emitted from the external of the solar cell 2 can have a decreasing refractive angle while being emitted from the air onto the second-type semiconductor surface 202 sequentially via the coverage layer 212, the second refraction part 2112 and the first refraction part 2111; and through the configurations and structural designs of the refraction convexes 211 and the coverage layer 212, the sunlight can be concentrately emitted onto the second-type semiconductor surface 202 and the solar cell 2 can have a higher light absorption effect consequently.

It is understood that the aforementioned materials (for example, the SiC, SiN and SiO₂) of the coverage layer 212, the second refraction part 2112 and the first refraction part 2111 are used for illustrations only; and the disclosure is not limited thereto. In other words, the coverage layer 212, the second refraction part 2112 and the first refraction part 2111 can be made of other materials if A>B>C; where A is indicated as the refractive index of the material of the first refraction part 2111, B is indicated as the refractive index of the material of the second refraction part 2112, and C is indicated as the refractive index of the material of the coverage layer 212.

As depicted in FIG. 2, the solar cell 2 in this embodiment further includes a first electrode 22, a second electrode 23 and a second antireflective layer 24. The first electrode 22 has two terminal ends 221, 222; wherein the terminal end 221 is connected to the second-type semiconductor surface 202 of the semiconductor substrate 20, and the terminal end 222 protrudes from the first antireflective layer 21. The second antireflective layer 24 is formed on the first-type semiconductor surface 201 of the semiconductor substrate 20. Similar to the first antireflective layer 21, the second antireflective layer 24 in another embodiment may also include a plurality of refraction convexes 211; and the disclosure is not limited thereto. The second electrode 23 has two terminal ends 231, 232; wherein the terminal end 231 is connected to the first-type semiconductor surface 201 of the semiconductor substrate 20, and the terminal end 232 protrudes from the second antireflective layer 24. In this embodiment the first electrode 22 and the second electrode 23 are configured to, for example, electrically connect to an external electronic device (not shown).

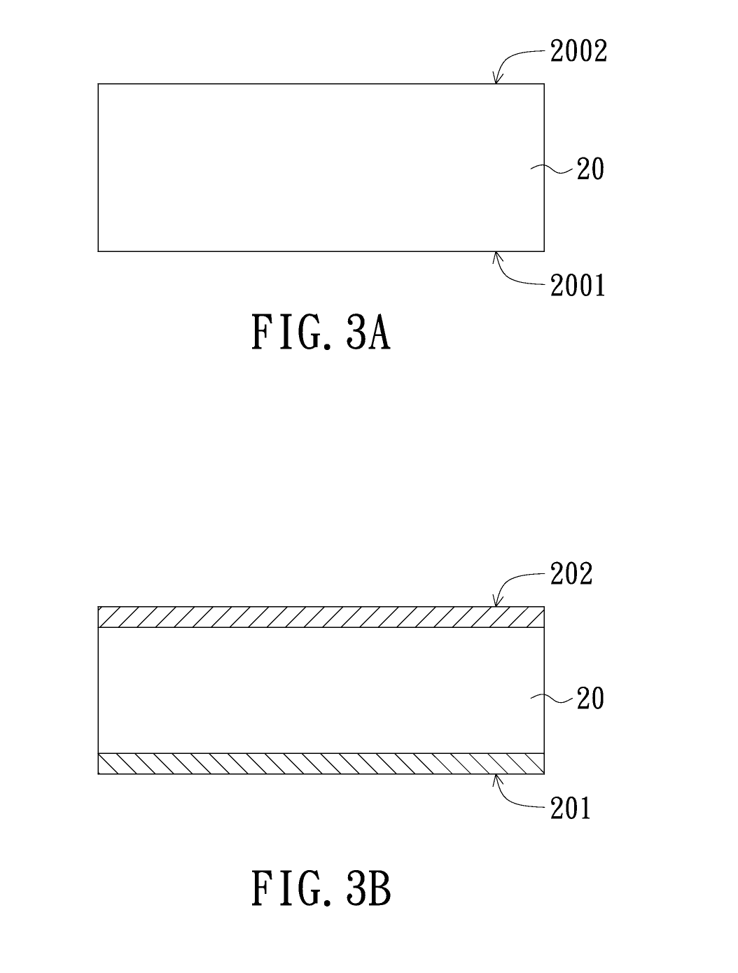

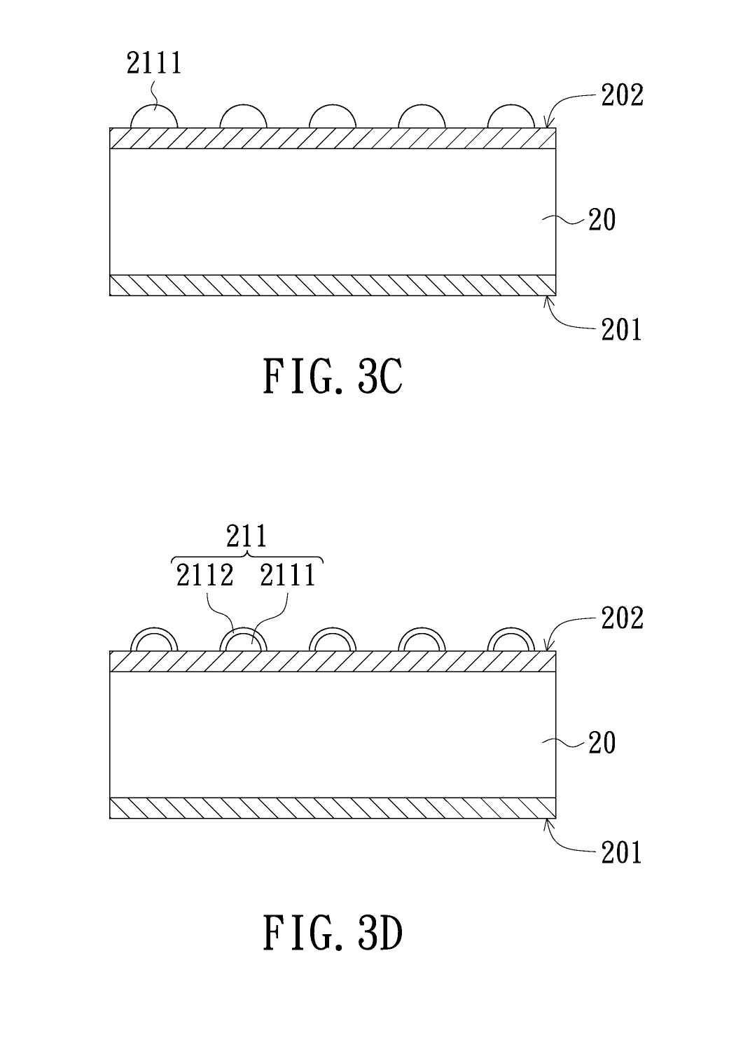

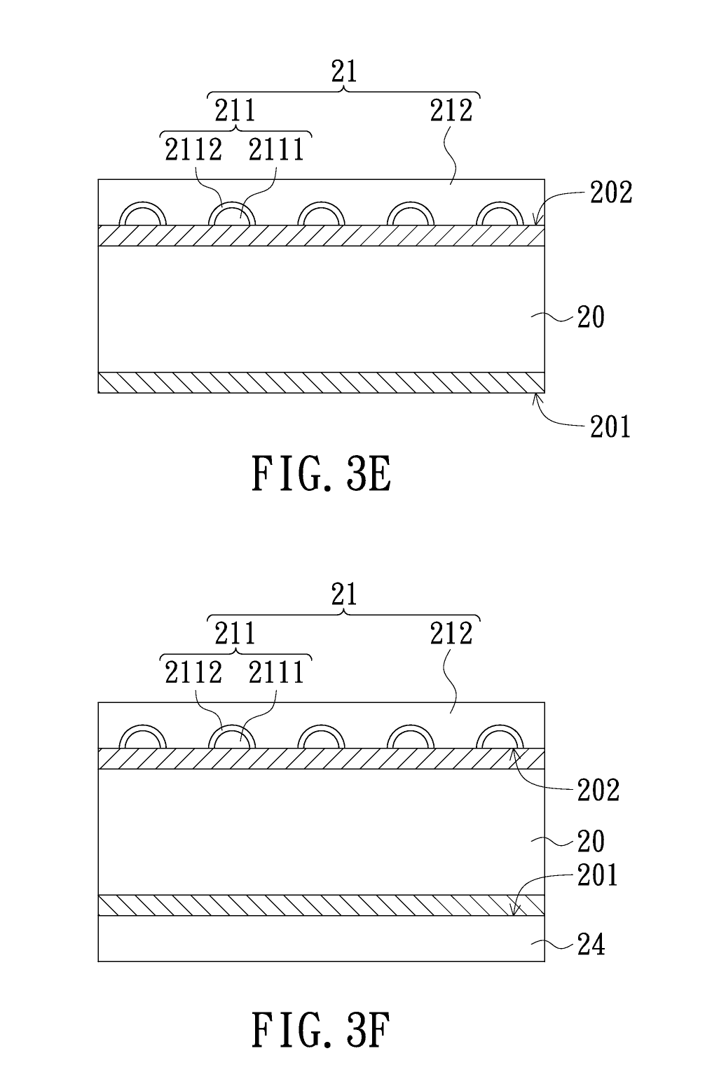

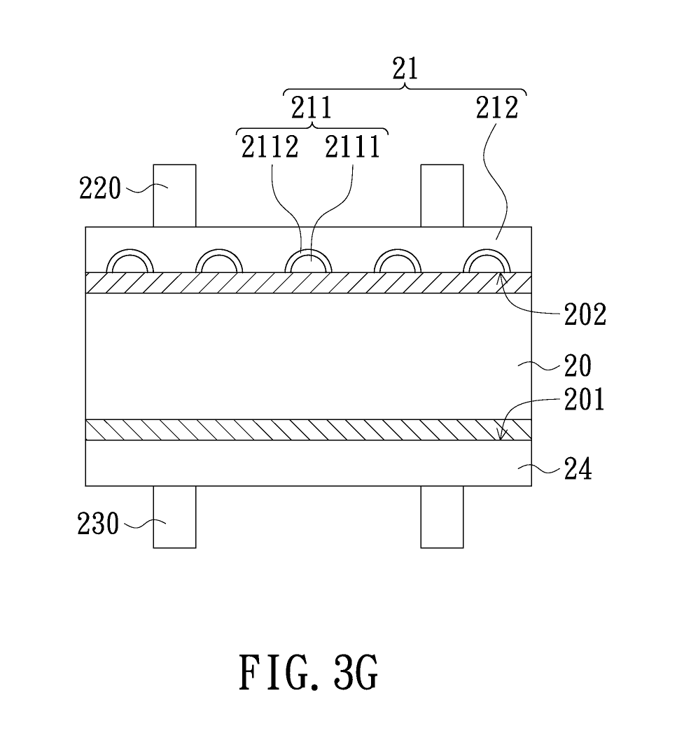

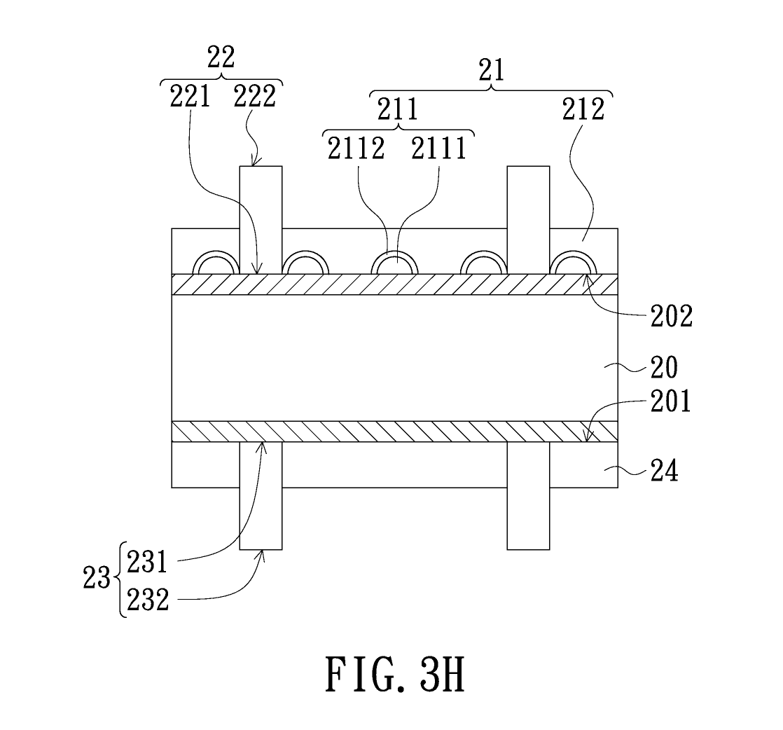

FIGS. 3A˜3H are schematic views illustrating a manufacturing process of the solar cell 2 shown in FIG. 2. First, as illustrated in FIG. 3A, the semiconductor substrate 20, with a first surface 2001 and a second surface 2002 opposite to each other, is provided. Next, as illustrated in FIG. 3B, the first surface 2001 of the semiconductor substrate 20 is converted into the first-type semiconductor surface 201 by being dopened with a first-type dopant; and the second surface 2002 of the semiconductor substrate 20 is converted into the second-type semiconductor surface 202 by being dopened with a second-type dopant. In this embodiment, the first-type dopant is a P-type element selected from the elements of group III (such as B or Al); the second-type dopant is an N-type element selected from the elements of group V (such as P, As or Sb). In addition, the mean of doping the first surface 2001 of the semiconductor substrate 20 with the first-type dopant as well as doping the second surface 2002 of the semiconductor substrate 20 with the second-type dopant can be realized by the ion diffusion method and the ion implantation method; and the disclosure is not limited thereto.

Afterwards, as illustrated in FIG. 3C, a first deposition process for forming a plurality of protruded first refraction parts 2111 on the second-type semiconductor surface 202 of the semiconductor substrate 20 is performed; wherein the first refraction part 2111 in this embodiment is made of SiC and has a refractive index of 2.6˜2.8. Afterwards, as illustrated in FIG. 3D, a second deposition process for forming the second refraction part 2112 on each first fraction part 2111 is performed; wherein the second refraction part 2112 in this embodiment is made of SiN and has a refractive index of 1.8˜2.2. Specifically, the second refraction parts 2111 are conformally coated on the respective first refraction parts 2111; and the second refraction parts 2111 and the first refraction parts 2111 corporately form the refraction convexes 211. Afterwards, as illustrated in FIG. 3E, a third deposition process for forming the coverage layer 212 on the second-type semiconductor surface 202 of the semiconductor substrate 20 and the refraction convexes 211 is performed; wherein the refraction convexes 211 and the coverage layer 212 corporately form the first antireflective layer 21 shown in FIG. 2; and the coverage layer 212 is made of SiO, and has a refractive index of 1.45.

It is to be noted that the first, second and third deposition processes illustrated in FIGS. 3C˜3E may be include the metal-organic chemical vapor deposition (MOCVD), the plasma enhanced chemical vapor deposition (PECVD), the atomic layer chemical vapor deposition process (ALD), the molecular beam epitaxy (MBE), the atmospheric pressure chemical vapor deposition process (APCVD), the electron cyclotron resonance chemical vapor deposition process (ECRCVD) or the ultra-high vacuum chemical vapor deposition process (UHVCVD); and the disclosure is not limited thereto.

Afterwards, as illustrated in FIG. 3F, the second antireflective layer 24 is formed on the first-type semiconductor surface 201 of the semiconductor substrate 20; wherein the second antireflective layer 24 is made of SiO and SiN. Afterwards, as illustrated in FIG. 3G, a first electrode pattern 220 is formed on the first antireflective layer 21 and a second electrode pattern 230 is formed on the second antireflective layer 24. Afterwards, as illustrated in FIG. 3H, a sintering process, for forming the first electrode 22 by making the first electrode pattern 220 pass through the first antireflective layer 21 so as to contact the second-type semiconductor surface 202 as well as forming the second electrode 23 by making the second electrode pattern 230 pass through the second antireflective layer 24 so as to contact the first-type semiconductor surface 201, is performed.

In summary, according to the solar cell and the manufacturing method thereof disclosed in the present disclosure, an antireflective layer constituted by a plurality of refraction convexes and a coverage layer is formed on a semiconductor substrate; wherein each refraction convex includes a first refraction part and a second refraction part, the first refraction parts are conformally coated with the respective second refraction parts, and the first refraction part is configured to have a refractive index greater than the refractive index of the second refraction part. According to the aforementioned antireflective layer structure, the solar cell of the present disclosure can have higher light absorption efficiency as well as higher photoelectric conversion efficiency. In addition, according to the solar cell manufacturing method of the present disclosure, the semiconductor substrate is prevented from being damaged due to the texture process is omitted. Thus, a poor conduction efficiency of the electrons and holes between the N-type and P-type semiconductor surfaces is avoided.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A solar cell, comprising:
a semiconductor substrate having a first-type semiconductor surface and a second-type semiconductor surface opposite to each other; and
a first antireflective layer, comprising:
a plurality of refraction convexes directly contacted the second-type semiconductor surface, each refraction convex comprising a first refraction part and a second refraction part, the first refraction parts being conformally coated with the respective second refraction parts, and the first refraction part being configured to have a refractive index greater than the refractive index of the second refraction part; and
a coverage layer formed to cover the second-type semiconductor surface and the refraction convexes, and the coverage layer being configured to have a refractive index smaller than the refractive index of the second refraction part.

2. The solar cell according to claim 1, wherein the first-type semiconductor surface is an N-type semiconductor surface, the second-type semiconductor surface is a P-type semiconductor surface.

3. The solar cell according to claim 1, wherein the first-type semiconductor surface is a P-type semiconductor surface, the second-type semiconductor surface is an N-type semiconductor surface.

4. The solar cell according to claim 1, wherein the first refraction part has a refractive index of 2.6˜2.8, the second refraction part has a refractive index of 1.82˜2.2, the coverage layer has a refractive index of 1.45.

5. The solar cell according to claim 1, wherein the material of the first refraction part is SiC, the material of the second refraction part is SiN, and the material of the coverage layer is SiO2.

6. The solar cell according to claim 1, wherein each of the plurality of the refraction convexes has an arc structure.

7. The solar cell according to claim 1, further comprising a first electrode configured to have its one terminal end connected to the second-type semiconductor surface and its another terminal end protruding from the first antireflective layer.

8. The solar cell according to claim 1, further comprising:
a second antireflective layer formed on the first-type semiconductor surface of the semiconductor substrate; and
a second electrode configured to have its one terminal end of connected to the first-type semiconductor surface and its another terminal end protruding from the second antireflective layer.

9. A solar cell manufacturing method, comprising:
providing a semiconductor substrate with a first surface and a second surface opposite to each other; and
forming a first antireflective layer on the second-type semiconductor surface, wherein the first antireflective layer comprises a plurality of refraction convexes and a coverage layer, each refraction convex comprises a first refraction part and a second refraction part, the first refraction parts are conformally coated with the respective second refraction parts, the first refraction part is configured to have a refractive index greater than the refractive index of the second refraction part, the coverage layer is formed to cover the second-type semiconductor surface and the refraction convexes, and the coverage layer is configured to have a refractive index smaller than the refractive index of the second refraction part.

10. The solar cell manufacturing method according to claim 9, wherein the formation of the second-type semiconductor surface comprises a step of doping a first surface of the semiconductor substrate with a second-type dopant, the formation of the first-type semiconductor surface comprises a step of doping a second surface of the semiconductor substrate with a first-type dopant.

11. The solar cell manufacturing method according to claim 10, wherein the mean of doping the first surface with the first-type dopant and doping the second surface with the second-type dopant comprises the ion diffusion method.

12. The solar cell manufacturing method according to claim 9, wherein the formation of the first antireflective layer on the second-type semiconductor surface comprises:
performing a first deposition process for forming the first refraction parts on the second-type semiconductor surface;
performing a second deposition process for forming the second refraction part on each first fraction part; and
performing a third deposition process for forming the coverage layer on the second-type semiconductor surface and the refraction convexes.

13. The solar cell manufacturing method according to claim 11, further comprising:
forming a second antireflective layer on the first-type semiconductor surface;
forming a first electrode pattern on the first antireflective layer and forming a second electrode pattern on the second antireflective layer; and
performing a sintering process for forming a first electrode by making the first electrode pattern pass through the first antireflective layer and contact the second-type semiconductor surface and forming a second electrode by making the second electrode pattern pass through the second antireflective layer and contact the first-type semiconductor surface.

14. The solar cell manufacturing method according to claim 9, wherein the first refraction part has a refractive index of 2.6˜2.8, the second refraction part has a refractive index of 1.8˜2.2, the coverage layer has a refractive index of 1.45.

15. The solar cell manufacturing method according to claim 9, wherein the material of the first refraction part is SiC, the material of the second refraction part is SiN, the material of the coverage layer is SiO2.

16. The solar cell according to claim 1, wherein each of the refraction convexes has a structure with a size of 70-18 100 microns.
